(19) United States
(12) Patent Application Publication
(10) Pub. No.: US 2025/0323671 A1
(43) Pub. Date: Oct. 16, 2025

(54) MULTIPORT INTERFEROMETRIC TRANSMITTER FOR CONCURRENT DUAL-BAND AND DUAL-POLARIZED TRANSMISSION AND METHODS THEREOF

(71) Applicants: Huawei Technologies Canada Co., Ltd., Kanata (CA); la corporation de I' École Polytechnique de Montréal, Montreal (CA)

(72) Inventors: Jie Deng, Montreal (CA); Pascal Burasa, Montreal (CA); Ke Wu, Saint-Laurent (CA)

(21) Appl. No.: 19/249,744

(22) Filed: Jun. 25, 2025

Related U.S. Application Data
(63) Continuation of application No. PCT/CA2023/050043, filed on Jan. 17, 2023.

(51) Int. Cl. H04B 1/04; H03F 3/24; H03F 3/68

(52) U.S. Cl. CPC H04B 1/04; H03F 3/245; H03F 3/68; H03F 2200/198; H03F 2200/451; H04B 2001/0408

(57) ABSTRACT

The present disclosure provides modules, arrays and methods for interferometric transmitters for dual-band and dual-polarization signal modulation where the module has a plurality of oscillators for generating a plurality of carrier signals of a plurality of frequency bands, and a multiport network connected to the plurality of oscillators. The multiport network having a plurality of inputs each for receiving one of the plurality of carrier signals, a plurality of outputs, and a plurality of reflection paths between the plurality of inputs and the plurality of outputs. Each of the plurality of reflection paths has a variable reflection coefficient for modulating the plurality of carrier signals to output a plurality of modulated radio-frequency (RF) signals of the plurality of frequency bands via the plurality of outputs.

### CROSS-REFERENCE TO RELATED APPLICATION

The present application is a continuation of Patent Cooperation Treaty Application Serial No. PCT/CA2023/050043, entitled “MULTIPORT INTERFEROMETRIC TRANSMITTER FOR CONCURRENT DUAL-BAND AND DUAL-POLARIZED TRANSMISSION AND METHODS THEREOF,” filed on Jan. 17, 2023, the entirety of which is incorporated by reference herein.

### TECHNICAL FIELD

The present disclosure relates generally to wireless transmitters, and in particular, to interferometric dual-band and dual-polarized transmitters.

### BACKGROUND

Wireless communications systems are rapidly developing as an increasing number of a variety of applications, such as virtual and augmented reality, have accelerated demand for high-speed communications systems and the equipment used therein. Transmission links having high data rates, high capacity, and high reliability are important to provide stable services meeting these requirements. An important component of such communications systems are transmitters, which may be commonly used to generate and send modulated signals. Transmitters in high-speed communications systems may face strict specifications and requirements to ensure high performance of the transmitter within such systems. To provide highly performing transmitters, innovative and disruptive technologies may be required for signal modulation.

Conventional interferometric transmitters are for single-band and single-polarization transmission and may be susceptible to noise and interference, and generally provide lower signal transmission efficiency than multi-polarization transmissions.

### SUMMARY

The present disclosure provides methods, modules, and transmitter arrays for a multiport interferometric transmitter for dual-band and dual-polarization transmission of signals by adjusting reflection coefficients of at least two variable networks which may comprise quadrature hybrid couplers, power dividers, 90-degree phase shifters, variable loads, quarter-wavelength transmission lines, local oscillators, amplifiers, and antennas, which may be implemented in a variety of technologies such as complementary-metal-oxide-semiconductor (CMOS).

According to one aspect of this disclosure, there is provided a module comprising: a first, a second, a third, and a fourth variable load; a 90-degree phase shifter; a first and a second carrier leakage suppression element; and a first, a second, a third, and a fourth quadrature hybrid coupler, each quadrature hybrid coupler comprising a first port, a second port, a third port, and a fourth port, wherein: the first port of the first coupler is for being energized by a first oscillation signal, the second port of the first coupler is connected to the second port of the second coupler, the third port of the first coupler is connected to the second port of the third coupler, the fourth port of the first coupler is for being energized by a second oscillation signal, the first port of the second coupler is connected to the first variable load via the first carrier leakage suppression element, the third port of the second coupler is connected to the second port of the fourth coupler via the 90-degree phase shifter, the fourth port of the second coupler is connected to the second variable load, the first port of the third coupler is connected to the third variable load via the second carrier leakage suppression element, the third port of the third coupler is connected to the third port of the fourth coupler, the fourth port of the third coupler is connected to the fourth variable load, the first port of the fourth coupler is for being energized by a first output signal, the fourth port of the fourth coupler is for being energized by a second output signal, the first output signal comprises a first modulated signal and a second modulated signal, and the second output signal comprises a third modulated signal and a fourth modulated signal.

In an embodiment, the first carrier leakage suppression element is a first quarter-wavelength (λ/4) transmission line.

In an embodiment, the second carrier leakage suppression element is a second λ/4 transmission line.

In an embodiment, the first carrier leakage suppression element is a first 90-degree wideband phase shifter.

In an embodiment, the second carrier leakage suppression element is a second 90-degree wideband phase shifter.

In an embodiment, the module further comprises: a first local oscillator for generating the first oscillation signal; and a second local oscillator for generating the second oscillation signal.

In an embodiment, the first local oscillator and the second local oscillator have substantially the same characteristic impedance.

In an embodiment, the module further comprises: a first amplifier connected to the first port of the fourth coupler for amplifying the first output signal to a first amplified signal; and a second amplifier connected to the fourth port of the fourth coupler for amplifying the second output signal to a second amplified signal.

In an embodiment, the module further comprises: a first antenna connected to the first amplifier for transmitting the first amplified signal; and a second antenna connected to the second amplifier for transmitting the second amplified signal.

In an embodiment, the first antenna is for being vertically polarized and the second antenna is for being horizontally polarized.

In an embodiment, each of the first, the second, the third, and the fourth variable loads each comprise a capacitor, a butterfly radio frequency choke, and a Schottky diode.

In an embodiment, the module comprises CMOS components.

In an embodiment, a transmitter array comprises a plurality of modules.

According to another aspect of this disclosure, there is a module comprising: a first and a second variable load; a 90-degree phase shifter; a first and a second power divider, each power divider comprising an input port, a first output port, and a second output port; a first and a second quadrature hybrid coupler, each quadrature hybrid coupler comprising a first port, a second port, a third port, and a fourth port, wherein: the first port of the first coupler is for being energized by a first oscillation signal, the second port of the first coupler is connected to the second output port of the first power divider, the third port of the first coupler is connected to the second output port of the second power divider, the fourth port of the first coupler is for being energized by a second oscillation signal, the first port of the second coupler is for being energized by a first output signal, the second port of the second coupler is connected to the first output port of the first power divider via the 90-degree phase shifter, the third port of the second coupler is connected to the first output port of the second power divider, the fourth port of the second coupler is for being energized by a second output signal, the input port of the first power divider is connected to the first variable load, the input port of the second power divider is connected to the second variable load, the first output signal comprises a first modulated signal and a second modulated signal, and the second output signal comprises a third modulated signal and a fourth modulated signal.

In an embodiment, the module further comprises: a first local oscillator for generating the first oscillation signal; and a second local oscillator for generating the second oscillation signal.

In an embodiment, the first local oscillator and the second local oscillator have substantially the same characteristic impedance.

In an embodiment, the module further comprises: a first amplifier connected to the first port of the fourth coupler for amplifying the first output signal to a first amplified signal; and a second amplifier connected to the fourth port of the fourth coupler for amplifying the second output signal to a second amplified signal.

In an embodiment, the module further comprises: a first antenna connected to the first amplifier for transmitting the first amplified signal; and a second antenna connected to the second amplifier for transmitting the second amplified signal.

In an embodiment, the first antenna is for being vertically polarized and the second antenna is for being horizontally polarized.

In an embodiment, each of the first and the second variable loads each comprise a capacitor, a butterfly radio frequency (RF) choke, and a Schottky diode.

In an embodiment, the module comprises CMOS components.

In an embodiment, a transmitter array comprising a plurality of modules.

According to another aspect of this disclosure, there is provided a method comprising the steps of: providing a first oscillating signal and a second oscillating signal to ports of a first quadrature hybrid coupler interconnected to a second quadrature hybrid coupler, the couplers interconnected with a first variable load network and a second variable load network; and adjusting reflection coefficients of the first variable network and/or the second variable network to produce a first output signal and a second output signal from ports of the second quadrature hybrid coupler, wherein the first output signal comprises a first modulated signal and a second modulated signal, and wherein the second output signal comprises a third modulated signal and a fourth modulated signal.

In an embodiment, adjusting reflection coefficients comprises adjusting loads of the first and second variable load networks.

In an embodiment, the method comprises the steps of: amplifying the first output signal; and amplifying the second output signal.

In an embodiment, the method further comprises the steps of: transmitting the first output signal from a vertically polarized antenna; and transmitting the second output signal from a horizontally polarized antenna.

In an embodiment, the first variable network and the second variable network each comprise a variable load.

In an embodiment, the first variable network and the second variable network each comprise an additional quadrature hybrid coupler.

In an embodiment, the first variable network and the second variable network each comprise a power divider.

According to another aspect of this disclosure, there is provided a module comprising: a plurality of oscillators for generating a plurality of carrier signals of a plurality of frequency bands; and a multiport network connected to the plurality of oscillators; wherein the multiport network comprises: a plurality of inputs each for receiving one of the plurality of carrier signals, a plurality of outputs, and a plurality of reflection paths between the plurality of inputs and the plurality of outputs; and wherein each of the plurality of reflection paths comprise a variable reflection coefficient for modulating the plurality of carrier signals to output a plurality of modulated radio-frequency (RF) signals of the plurality of frequency bands via the plurality of outputs.

In an embodiment, the plurality of reflection paths comprises one or more quadrature hybrid couplers.

In an embodiment, the plurality of reflection paths comprises one or more power dividers.

In an embodiment, the module comprises one or more variable loads, each for adjusting one of the variable reflection coefficients.

In an embodiment, each of the variable loads comprises a capacitor, a butterfly radio frequency choke, and a Schottky diode.

In an embodiment, the module comprises one or more carrier leakage suppression elements.

In an embodiment, the plurality of reflection paths comprises one or more 90-degree wideband phase shifters.

In an embodiment, the module further comprises: a plurality of antennas each connected to one of the plurality of outputs; wherein two of the plurality of antennas have different polarization characteristics.

In an embodiment, each of the antennas comprises an amplifier.

According to one aspect of this disclosure, there is provided an apparatus comprising means to carry out the above mentioned methods.

In an embodiment, the apparatus may comprise a transmitter array mentioned above, a module mentioned above, or a chipset.

According to one aspect of this disclosure, there is provided a system comprising apparatus mentioned above and a receiver.

### BRIEF DESCRIPTION OF THE DRAWINGS

For a more complete understanding of the disclosure, reference is made to the following description and accompanying drawings, in which:

FIG. 1 is a schematic of an embodiment of a transmitter module;

FIGS. 2A and 2B are schematic diagrams of baseband control circuits;

FIGS. 3A and 3B are Smith charts showing reflection coefficient maps of the module of FIG. 1 at 24 GHz and 28 GHz;

FIGS. 4A and 4B are waveforms of modulated signals for vertical and horizontal polarizations of the module of FIG. 1 at 24 GHz;

FIGS. 5A and 5B are normalized constellation diagrams for horizontal and vertical polarization of the module of FIG. 1 at 24 GHz;

FIGS. 6A and 6B are waveforms of modulated signals for vertical and horizontal polarizations of the module of FIG. 1 at 28 GHZ;

FIGS. 7A and 7B are normalized constellation diagrams for horizontal and vertical polarization of the module of FIG. 1 at 28 GHZ;

FIG. 8 is a schematic of an alternative embodiment of a transmitter module;

FIG. 9 is a schematic of a transmitter array comprising modules of the present disclosure; and

FIG. 10 is a block diagram of a method for transmitting a dual-band and dual-polarized signal in accordance with representative embodiments of the present disclosure.

### DETAILED DESCRIPTION

Unless otherwise defined, all technical and scientific terms used herein generally have the same meaning as commonly understood by one of ordinary skill in the art to which this disclosure pertains. Exemplary terms are defined below for ease in understanding the subject matter of the present disclosure.

Multiport interferometric technologies may be suitable for application in radio frequency (RF) front-end solutions for receiving and transmitting RF signals with lower costs and power consumption requirements as a result of its simple working principles, compared to alternative technologies. Unlike multiport interferometric receivers which require the use of additional mixers and non-linear mixing approaches, multiport interferometric transmitters may up-convert a baseband signal to an RF signal without the use of additional mixers using linear interference techniques, which reduces power requirements and facilitates filtering as necessary. Therefore, multiport interferometric transmitters may be used to replace mixer technology-based conventional up-conversion transmitters and may provide several advantages in terms of frequency re-configurability, design simplicity, low-cost fabrication, and low-power consumption. These advantages make multiport interferometric receivers suitable for use in high-speed communications systems, such as existing 5G networks, future 6G networks, and/or the like.

The use of multi-band and multi-polarization in transmitters may also further expand the capabilities of communications systems by enhancing communications channels and throughput. Further, the use of polarization selectivity in signal modulation may enable channel diversity. A dual-polarization transmitter may support simultaneous independent data streams on the same carrier frequency, which may double the effective channel capacity at that carrier frequency. While multi-band and multi-polarization transmitters may offer high quality transmission, conventional multiport interferometric transmitters generally cannot provide dual-band and dual-polarization transmission simultaneously using only a single multiport correlator. Some of the embodiments disclosed herein provide interferometric transmitters capable of simultaneously providing dual-band and dual-polarized modulated signals for diverse wireless applications and services, such as portable devices, base stations, terminal devices, radar systems, satellite communication systems, and/or the like.

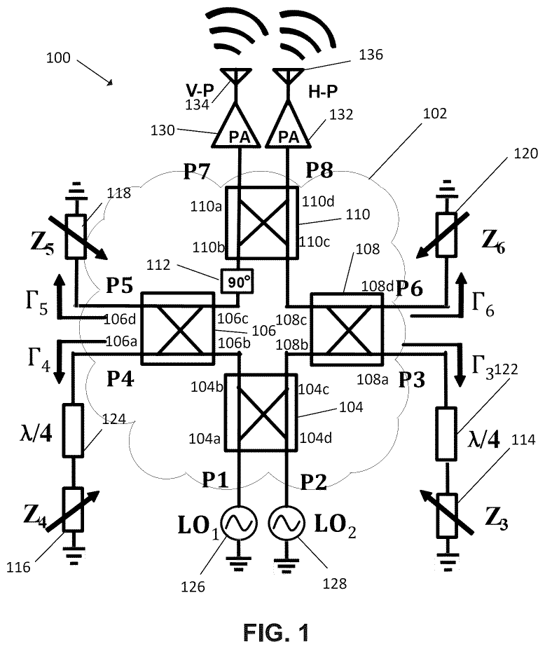

FIG. 1 shows the architecture of an embodiment of an interferometric receiver module 100, which comprises a multiport network 102 as a core component that determines the overall performance of the module 100 in a system. In some embodiments disclosed herein, the multiport network 102 comprises at least a first, a second, a third, and a fourth quadrature hybrid coupler 104, 106, 108 and 110, and a 90-degree phase shifter 112, wherein each coupler 104, 106, 108, 110 comprises four ports. The multiport network 102 may receive oscillation signals at a first port 104a of the first coupler 104 and a fourth port 104d of the first coupler 104. The couplers 104, 106, 108 and 110 are interconnected, wherein the couplers 106 and 110 are coupled to the 90-degree phase shifter 112. Specifically,
a second port 104b of the first coupler 104 is connected to a second port 106b of the second coupler 106, and a third port 104c of the first coupler 104 is connected to a second port 108b of the third coupler 108;
a first port 106a of the second coupler 106 is connected to a first variable load 116 via a first carrier leakage suppression element 124, a third port 106c of the second coupler 106 is connected to a second port 110b of the fourth coupler 110 via the 90-degree phase shifter 112, and a fourth port 106d of the second coupler 106 is connected to a second variable load 118;
a first port 108a of the third coupler 108 is connected to a third variable load 114 via a second carrier leakage suppression element 122, a third port 108c of the third coupler 108 is connected to a third port 110c of the fourth coupler 110, and a fourth port 108d of the third coupler 108 is connected to a fourth variable load 120;
a first port 110a of the fourth coupler 110 is for being energized by a first output signal, and a fourth port 110d of the fourth coupler 110 is for being energized by a second output signal.

The first output signal comprises a first modulated signal and a second modulated signal, and the second output signal comprises a third modulated signal and a fourth modulated signal, wherein the first and second modulated signals may be vertically polarized and the third and fourth modulated signals may be horizontally polarized. The first and second carrier leakage suppression elements 124 and 122 may be quarter-wavelength (λ/4) transmission lines. Alternatively, the first and second carrier leakage suppression elements 124 and 122 may be 90-degree wideband phase shifters.

In some embodiments, the module 100 may comprise a first and a second local oscillator (LO) 126 and 128 for providing the oscillation signals to the first port 104a and the fourth port 104d of the first coupler 104. The first and second local oscillators 126 and 128 may have substantially the same characteristic impedance. In some embodiments, the module 100 may comprise a first amplifier 130 and a first antenna 134 for amplifying and transmitting the first output signal and a second amplifier 132 and a second antenna 136 for amplifying and transmitting the second output signal.

As the module 100 may receive dual LO signal inputs and provides dual-band RF output signals (comprising the first and second output signals in different bands), the architecture of the module 100 provides concurrent dual-band and dual-polarized signal modulation, distinguishing it from conventional single-band and single-polarized interferometric transmitters.

During the operation of the module 100, two LO signals α_{LO1} and α_{LO2} generated by the first LO 126 (LO₁) and the second LO 128 (LO₂) enter the first and second input ports (P1 and P2), being the first and fourth ports 104a and 104d of the first module 104. The first and second LO 126 and 128 may have substantially the same characteristic impedance to match the first and second input ports P1 and P2, which also absorb reflected signals. The LO signals from the first and second LOs 126 and 128 propagate via different paths to the first port 108a of the third coupler 108 (P3), the first port 106a of the second coupler 106 (P4), the fourth port 106d of the second coupler 106 (P5), and the fourth port (108d) of the third coupler 108 (P6) of the multiport network 102, and may be reflected because of the first variable load 116 (Z₄), the second variable load 118 (Z₅), the third variable load 114 (Z₃), and the fourth variable load 120 (Z₆). The variable loads may be controlled by baseband signals to vary or otherwise control the reflection coefficients of variable loads for modulating the reflected RF signals RF modulation. The modulated reflected signals, which bear the information of the baseband signals, propagate to the output ports (P7 and P8), being the first and fourth ports 110a and 110d of the fourth coupler 110, for RF transmission. The amplitude and phase of modulated signals α_{RF1} and α_{RF2} may be controlled by the variable loads (Z₃-Z₆) as follows:

$${a}_{RF 1 \_ P 7} = - {a}_{\_ LO 1} [ ( {Γ}_{4 \_ RF 1} + {Γ}_{5 \_ RF 1} ) j + ( {Γ}_{3 \_ RF 1} + {Γ}_{6 \_ RF 1} ) ] / 4 \qquad ( 1 )$$

$${a}_{RF 2 \_ P 7} = - {a}_{\_ LO 2} [ ( {Γ}_{4 \_ RF 2} + {Γ}_{5 \_ RF 2} ) j + ( {Γ}_{3 \_ RF 2} + {Γ}_{6 \_ RF 2} ) ] / 4 \qquad ( 2 )$$

$${a}_{RF 1 \_ P 8} = - {a}_{\_ LO 1} [ ( {Γ}_{4 \_ RF 1} + {Γ}_{5 \_ RF 1} ) j + ( {Γ}_{3 \_ RF 1} + {Γ}_{6 \_ RF 1} ) j ] / 4 \qquad ( 3 )$$

$${a}_{RF 2 \_ P 8} = - {a}_{\_ LO 2} [ ( {Γ}_{4 \_ RF 2} + {Γ}_{5 \_ RF 2} ) j + ( {Γ}_{3 \_ {RF}_{2}} + {Γ}_{6 \_ RF 2} ) j ] / 4 \qquad ( 4 )$$

where α_{RF1_P7} and α_{RF2_P7} represent two different modulated signals in port P7, α_{RF1_P8} and α_{RF2_P8} represent two different modulated signals in port P8, and Γ₃, Γ₄, Γ₅, and Γ₆ represent reflection coefficients of ports P3 to P6, respectively.

The modulated signals may be amplified by first and second amplifiers 130 and 132 and transmitted by the first and second antennas 134 and 136. To achieve dual-polarization transmission, the antennas 134 and 136 connected to ports P7 and P8 have different polarization characteristics. For example, the first antenna 134 for the transmitting the first output signal from port P7 may be vertically polarized, and the second antenna 136 for transmitting the second output signal from port P8 may be horizontally polarized, where both the first and second antennas 134 and 136 may be linearly polarized antennas. Linearly vertically polarized and linearly horizontally polarized RF waves emitted by the first and second antennas 134 and 136 may recombine at a receiver to provide a signal with arbitrary polarization. Such an arbitrary polarization can be described by elliptical polarization with orientation angle αₚ and ellipticity angle αₚ. Therefore, the transmitted signal from the vertically polarized antenna 134 and horizontally polarized antenna 136 may be expressed as:

$${a}_{RF 1 \_ P 7} = {{a}_{LO 1} [ ( {\vert {a}_{RF 1 \_ P 7} \vert}^{2} + {\vert {a}_{RF 1 \_ P 8} \vert}^{2} ) / {\vert {a}_{RF 1 \_ P 8} \vert}^{2} ]}^{- 1 / 2} ⋆ [ \text{} cos {α}_{{f}_{1}} cos {β}_{{f}_{1}} - j sin {α}_{f 1} sin {β}_{f 1} ] {e}^{j ( ∠ {a}_{RF 1 \_ P 7} - ∠ aLO 1 - ϕ1 )} \qquad ( 5 )$$

$${a}_{RF 1 \_ P 8} = {{a}_{LO 1} [ ( {\vert {a}_{RF 1 \_ P 7} \vert}^{2} + {\vert {a}_{RF 1 \_ P 8} \vert}^{2} ) / {\vert {a}_{RF 1 \_ P 8} \vert}^{2} ]}^{- 1 / 2} ⋆ [ \text{} sin {α}_{{f}_{1}} cos {β}_{{f}_{1}} + j sin {β}_{f 1} cos {α}_{f 1} ] {e}^{j ( ∠ {a}_{RF 1 \_ P 7} - ∠ aLO 1 - ϕ1 )} \qquad ( 6 )$$

$${a}_{RF 2 \_ P 7} = {{a}_{LO 2} [ ( {\vert {a}_{RF 2 \_ P 7} \vert}^{2} + {\vert {a}_{RF 2 \_ P 8} \vert}^{2} ) / {\vert {a}_{RF 2 \_ P 8} \vert}^{2} ]}^{- 1 / 2} ⋆ [ \text{} cos {α}_{{f}_{2}} cos {β}_{{f}_{2}} - j sin {α}_{f 2} sin {β}_{f 2} ] {e}^{j ( ∠ {a}_{RF 2 \_ P 7} - ∠ aLO 2 - ϕ2 )} \qquad ( 7 )$$

$${a}_{RF 2 \_ P 8} = {{a}_{LO 2} [ ( {\vert {a}_{RF 2 \_ P 7} \vert}^{2} + {\vert {a}_{RF 2 \_ P 8} \vert}^{2} ) / {\vert {a}_{RF 2 \_ P 8} \vert}^{2} ]}^{- 1 / 2} ⋆ [ \text{} sin {α}_{{f}_{2}} cos {β}_{f 2} + j sin {β}_{f 2} cos {α}_{f 2} ] {e}^{j ( ∠ {a}_{RF 2 \_ P 7} - ∠ aLO 2 - ϕ2 )} \qquad ( 8 )$$

where ϕ1 is the phase of the modulated signal α_{RF1}, and ϕ2 is the phase of the modulated signal α_{RF2}. Using equations (1)-(4) and equations (5)-(8), the following equations may be derived:

$$( {Γ}_{4 \_ RF 1} + {Γ}_{5 \_ RF 1} ) = {2 [ ( {\vert {a}_{RF 1 \_ P 7} \vert}^{2} + {\vert {a}_{RF 1 \_ P 8} \vert}^{2} ) / {\vert {a}_{RF 1 \_ P 8} \vert}^{2} ]}^{- 1 / 2} ⋆ ( cos {β}_{p \_ f 1} - sin {β}_{p \_ f 1} ) {e}^{j ( ∠ {a}_{RF 1 \_ P 7} - ∠ a LO 1 - ϕ1 + ap \_ f 1 + π / 2 )} \qquad ( 9 )$$

$$( {Γ}_{3 \_ RF 1} + {Γ}_{6 \_ RF 1} ) = {2 [ ( {\vert {a}_{RF 1 \_ P 7} \vert}^{2} + {\vert {a}_{RF 1 \_ P 8} \vert}^{2} ) / {\vert {a}_{RF 1 \_ P 8} \vert}^{2} ]}^{- 1 / 2} ⋆ ( cos {β}_{p \_ f 1} + sin {β}_{p \_ f 1} ) {e}^{j ( ∠ {a}_{RF 1 \_ P 7} - ∠ aLO 1 - ϕ1 + ap \_ f 1 + π )} \qquad ( 10 )$$

$$( {Γ}_{4 \_ RF 2} + {Γ}_{5 \_ RF 2} ) = {2 [ ( {\vert {a}_{RF 2 \_ P 7} \vert}^{2} + {\vert {a}_{RF 2 \_ P 8} \vert}^{2} ) / {\vert {a}_{RF 2 \_ P 8} \vert}^{2} ]}^{- 1 / 2} ⋆ ( cos {β}_{p \_ f 2} - sin {β}_{p \_ f 2} ) {e}^{j ( ∠ {a}_{RF 2 \_ P 7} - ∠ a LO 2 - ϕ2 + ap \_ f 2 + π / 2 )} \qquad ( 11 )$$

$$( {Γ}_{3 \_ RF 2} + {Γ}_{6 \_ RF 2} ) = {2 [ ( {\vert {a}_{RF 2 \_ P 7} \vert}^{2} + {\vert {a}_{RF 2 \_ P 8} \vert}^{2} ) / {\vert {a}_{RF 2 \_ P 8} \vert}^{2} ]}^{- 1 / 2} ⋆ ( cos {β}_{p \_ f 2} + sin {β}_{p \_ f 2} ) {e}^{j ( ∠ {a}_{RF 2 \_ P 7} - ∠ aLO 2 - ϕ2 + ap \_ f2 + π )} \qquad ( 12 )$$

From the ratio of equations (9) and (10), the relationship between α_{p_f1} and β_{p_f1} may be expressed as:

$${α}_{p \_ {f}_{1}} = π / 4 + [ ∠ ( {Γ}_{4 \_ RF 1} + {Γ}_{5 \_ RF 1} ) - ( {Γ}_{3 \_ RF 1} + {Γ}_{6 \_ RF 1} ) ] \qquad ( 13 )$$

$${β}_{p \_ {f}_{1}} = arctan [ ( \vert {Γ}_{3 \_ RF 1} + {Γ}_{6 \_ RF 1} \vert - \vert {Γ}_{4 \_ RF 1} + {Γ}_{5 \_ RF 1} \vert ) \text{} / ( \vert {Γ}_{3 \_ RF 1} + {Γ}_{6 \_ RF 1} \vert + \vert {Γ}_{4 \_ RF 1} + {Γ}_{5 \_ RF 1} \vert ) ] \qquad ( 14 )$$

From the ratio of equations (11) and (12), the relationship between α_{p_f2} and β_{p_f2} may be expressed as:

$${α}_{p \_ {f}_{2}} = π / 4 + [ ∠ ( {Γ}_{4 \_ RF 2} + {Γ}_{5 \_ RF 2} ) - ( {Γ}_{3 \_ RF 1} + {Γ}_{6 \_ RF 1} ) ] \qquad ( 15 )$$

$${β}_{p \_ {f}_{2}} = arctan [ ( \vert {Γ}_{3 \_ RF 2} + {Γ}_{6 \_ RF 2} \vert - \vert {Γ}_{4 \_ RF 2} + {Γ}_{5 \_ RF 2} \vert ) \text{} / ( \vert {Γ}_{3 \_ RF 2} + {Γ}_{6 \_ RF 2} \vert + \vert {Γ}_{4 \_ RF 2} + {Γ}_{5 \_ RF 2} \vert ) ] \qquad ( 16 )$$

As can be seen from the above equations (13)-(16), the polarization characteristics of the modulated signals α_{RF1} and α_{RF2} may be controlled by the variable loads.

The module 100 provides the capability for concurrent dual-band and dual-polarization transmission, wherein the polarization of modulated signals may be accomplished by controlling the reflection coefficients of variable loads.

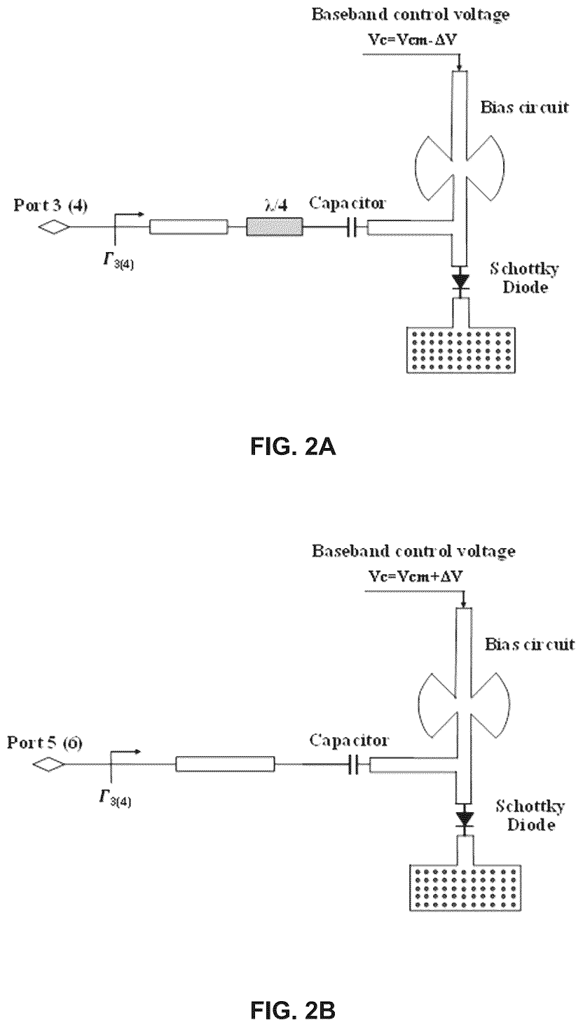

FIGS. 2A and 2B illustrate some embodiments of the first, the second, the third, and the fourth variable loads 116, 118, 114 and 120 each comprising an input microstrip line 184, a capacitor 192, a butterfly radio frequency choke 190, and a Schottky diode 194. More specifically, FIG. 2A illustrates some embodiments of the first and the third variable loads 116 and 114 (Z₃ and Z₄) while FIG. 2B illustrates some embodiments of the second and the fourth variable loads 118 and 120 (Z₅ and Z₆), wherein the first and third variable loads 116 and 114 each comprise a λ/4 transmission line 186.

In some embodiments, the module 100 may be for transmitting in the Ka-band (between about 26.5 gigahertz (GHz) to about 40 GHz), which the following discussion relates to. To modulate an RF signal, a baseband signal is applied to the variable loads. FIGS. 2A and 2B illustrate some detail of baseband control circuits. Variable load is achieved by a Schottky diode due to its response speed, low complexity, and low power consumption. Other options such as the transistor, switch, and/or the like, may also be used as a variable load. A baseband control voltage is used to change the bias of a diode and generate different reflection coefficients. A capacitor may be used to eliminate the bias current that may be otherwise caused by the baseband voltage. A butterfly RF choke may be used to prevent unwanted RF signals. First and second leakage suppression elements 124 and 122 may be used to suppress carrier leakage. The suppression elements 124 and 122 may be two quarter-wavelength (λ/4) transmission lines or 90-degree wideband phase shifters. When a differential voltage is applied to the baseband control circuit at ports P3 and P5, the reflection coefficient at ports P3 and P5 may be expressed as:

$${Γ}_{3 \_ RF 1} \approx {Γ}_{o} + σΔυ and {Γ}_{5 \_ RF 1} \approx - {Γ}_{o} + σΔυ \qquad ( 17 )$$

$${Γ}_{3 \_ RF 1} \approx {Γ}_{o} + σΔυ and {Γ}_{4 \_ RF 2} \approx - {Γ}_{o} + σΔυ \qquad ( 18 )$$

where Γₒ is the reflection coefficient generated by the common mode voltage V_{cm} and σ is the first derivative of Γ at V_{cm}.

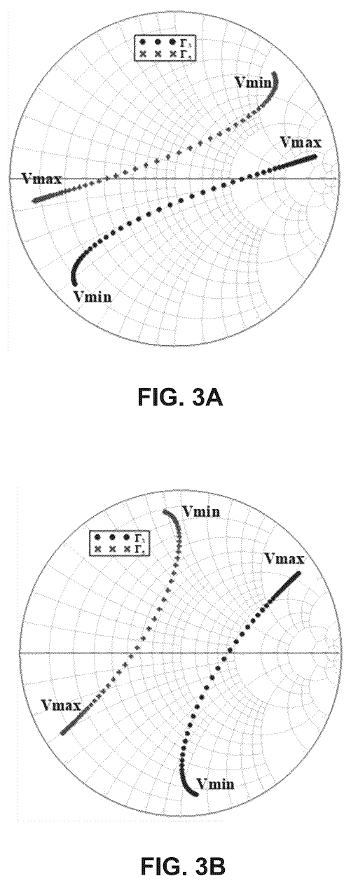

From equations (17) and (18), Γ_{total_RF1}=Γ_{3_RF1}+Γ_{5_RF1}=2σΔν and Γ_{total_RF2}=Γ_{3_RF2}+Γ_{5_RF2}=2σΔν. The reflection coefficient Γₒ is eliminated and there is no carrier leakage. The reflection coefficients of the baseband control circuit for ports P3 and P5 are illustrated in FIGS. 3A and 3B. A baseband control voltage from Vₘᵢₙ=0.1 volts (V) to Vₘₐₓ=0.5 V may produce two linear reflection coefficients with approximately symmetrical steps at 24 GHz (FIG. 3A) and 28 GHz (FIG. 3B). Based on the same baseband control circuits, the module 100 may modulate two different frequencies, simultaneously.

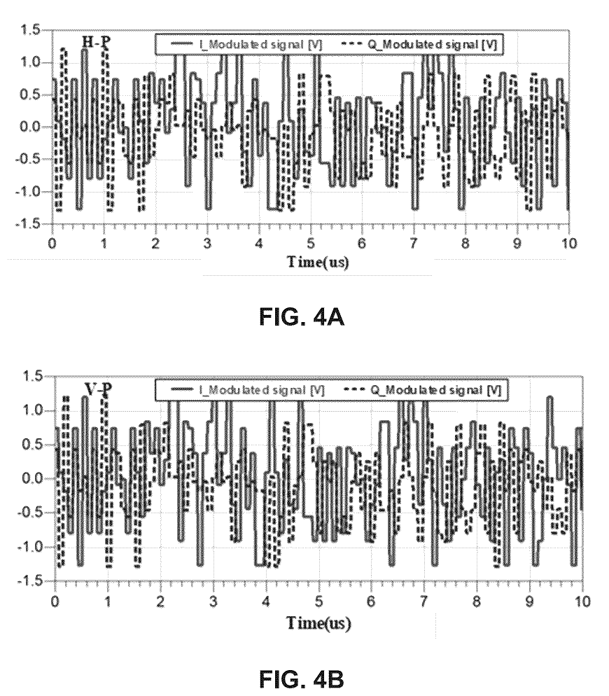

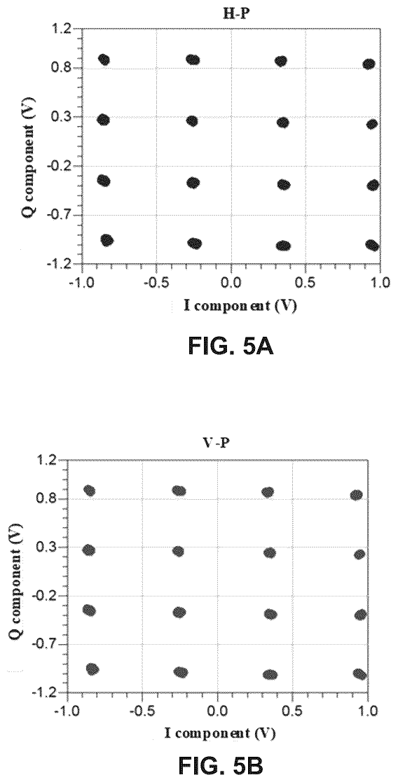

FIGS. 4A and 4B illustrate waveforms of a modulated signals for vertical and horizontal polarization, wherein the modulated signal is a 16 quadrature modulation (QAM) signal with 100 mega-samples per second (MSps) at a 24-GHz carrier frequency. The I and Q signal components represent a pseudo-random sequence. FIGS. 5A and 5B illustrate normalized constellation diagrams for modulated horizontal polarization and vertical polarization. Both modulated constellation diagrams are clear and the error vector magnitudes (EVMs) are around 3%.

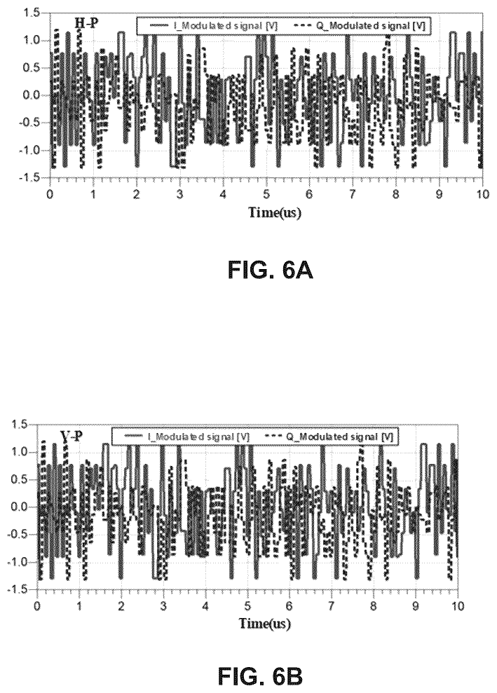

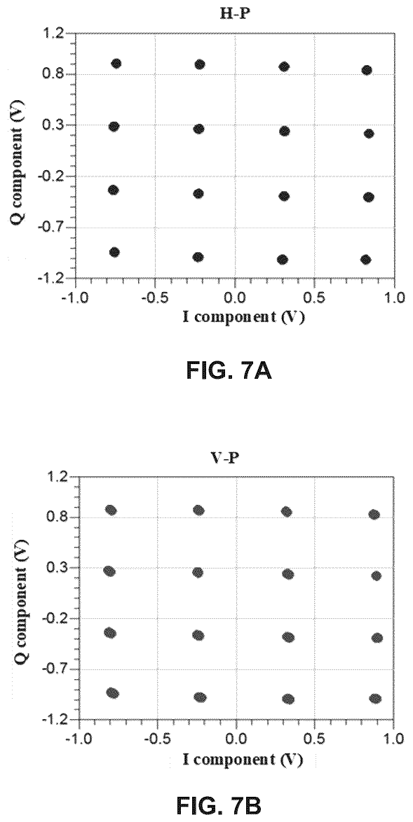

Similarly, FIGS. 6A and 6B illustrate waveforms of the modulated signals for vertical and horizontal polarization at 28 GHz, wherein the modulated signal is a 16-QAM signal with 100-MSps. FIGS. 7A and 7B illustrate modulated horizontal polarization and vertical polarization normalized constellation diagrams. Both modulated constellation diagrams are clear and the EVMs are around 2%.

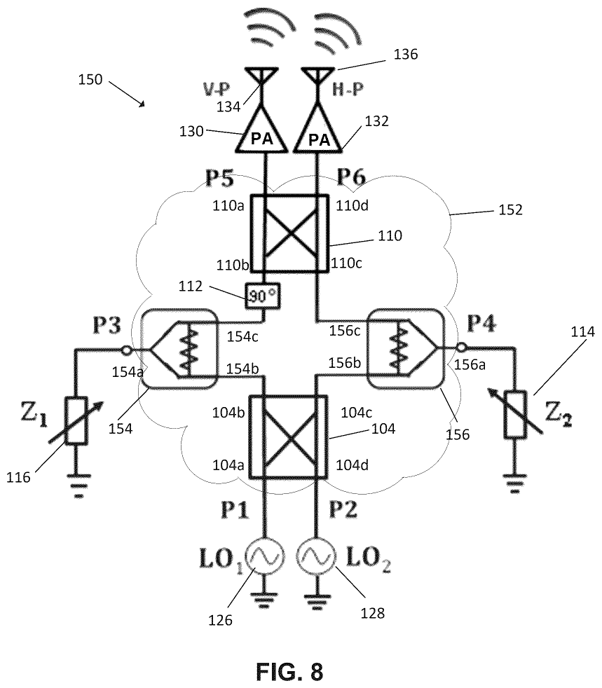

FIG. 8 illustrates an alternative embodiment of a module 150 wherein the multiport network 152 comprises two couplers, two power dividers, and a 90-degree phase shifter. The multiport network 152 differs from the multiport network 102 in that the second coupler 106 is replaced by a first power divider 154 and the third coupler 108 is replaced by a second power divider 156. Each power divider 154 and 156 comprise three ports. The connections of the components of the multiport network 102 are as follows:
a first port 154a of the first power divider 154 is connected to the first variable load 116,
a second port 154b of the first power divider 154 is connected to the second port 104b of the first coupler 104,
a third port 154c of the first power divider 154 is connected to the second port 110b of the fourth coupler 110 via the 90-degree phase shifter 112,
a first port 156a of the second power divider 156 is connected to the third variable load 114,
a second port 156b of the second power divider 156 is connected to the third port 104c of the first coupler 104, and
a third port 156c of the first power divider 156 is connected to the third port 110c of the fourth coupler 110.

The module 150 comprises half the variable load of the module 100, thereby further reducing the complexity of the module architecture. The module 150 has a lower power consumption due to the reduction of required bias circuits. However, the module 150 has increased requirements for the parameters of the variable loads. For example, for the same modulation requirement, the module 150 requires a wider range of impedance variations to generate different reflection coefficients than the module 100, where the coefficients may be approximately linear.

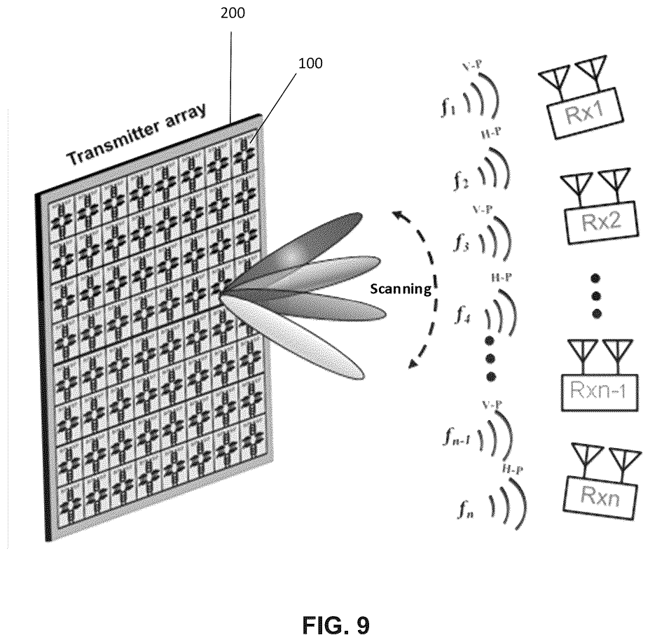

The transmitter modules 100 and 150 may be arranged, assembled, constructed, or otherwise used in a transmitter array 200 as illustrated in FIG. 9. The transmitter array 200 may enable multi-beam scanning to transmit modulated signals having different frequencies. The transmitter array may be used for multi-function applications such as sensing, imaging, angle/polarization detection, and/or the like, and may be implemented with a printed circuit board (PCB), metallic waveguides, complementary metal-oxide-semiconductor (CMOS), silicon micromachining, and/or the like.

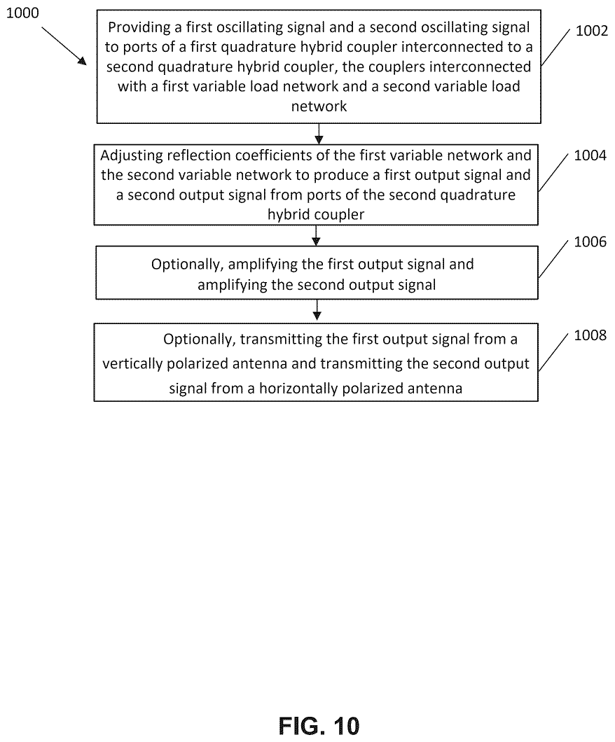

FIG. 10 is a flowchart showing the steps of a method 1000, according to some embodiments of the present disclosure. The method 1000 begins with providing a first oscillating signal and a second oscillating signal to ports of a first quadrature hybrid coupler interconnected to a second quadrature hybrid coupler, the couplers interconnected with a first variable load network and a second variable load network (step 1002). At step 1004, reflection coefficients of the first variable network and the second variable network are adjusted to produce a first output signal and a second output signal from ports of the second quadrature hybrid coupler. Optionally, at step 1006, the first and the second output signals are amplified. Optionally, at step 1008, the first output signal is transmitted from a vertically polarized antenna and the second output signal is transmitted from a horizontally polarized antenna.

Embodiments have been described above in conjunctions with aspects of the present invention upon which they may be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

Although the present invention has been described with reference to specific features and embodiments thereof, it is evident that various modifications and combinations may be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. A circuit comprising:
a first variable load, a second variable load, a third variable load, and a fourth variable load;
a 90-degree phase shifter;
a first carrier leakage suppression element and a second carrier leakage suppression element; and
a first quadrature hybrid coupler, a second quadrature hybrid coupler, a third quadrature hybrid coupler, and a fourth quadrature hybrid coupler, each quadrature hybrid coupler comprising a first port, a second port, a third port, and a fourth port,
wherein:
the first port of the first quadrature hybrid coupler is for being energized by a first oscillation signal,
the second port of the first quadrature hybrid coupler is connected to the second port of the second quadrature hybrid coupler,
the third port of the first quadrature hybrid coupler is connected to the second port of the third quadrature hybrid coupler,
the fourth port of the first quadrature hybrid coupler is for being energized by a second oscillation signal,
the first port of the second quadrature hybrid coupler is connected to the first variable load via the first carrier leakage suppression element,
the third port of the second quadrature hybrid coupler is connected to the second port of the fourth quadrature hybrid coupler via the 90-degree phase shifter,
the fourth port of the second quadrature hybrid coupler is connected to the second variable load,
the first port of the third quadrature hybrid coupler is connected to the third variable load via the second carrier leakage suppression element,
the third port of the third quadrature hybrid coupler is connected to the third port of the fourth quadrature hybrid coupler,
the fourth port of the third quadrature hybrid coupler is connected to the fourth variable load,
the first port of the fourth quadrature hybrid coupler is for being energized by a first output signal,
the fourth port of the fourth quadrature hybrid coupler is for being energized by a second output signal,
the first output signal comprises a first modulated signal and a second modulated signal, and
the second output signal comprises a third modulated signal and a fourth modulated signal.

2. The circuit of claim 1, wherein the first carrier leakage suppression element is a first quarter-wavelength (λ/4) transmission line.

3. The circuit of claim 1, wherein the second carrier leakage suppression element is a second λ/4 transmission line.

4. The circuit of claim 1, wherein the first carrier leakage suppression element is a first 90-degree wideband phase shifter.

5. The circuit of claim 1, wherein the second carrier leakage suppression element is a second 90-degree wideband phase shifter.

6. The circuit of claim 1, further comprising:
a first local oscillator for generating the first oscillation signal; and
a second local oscillator for generating the second oscillation signal.

7. The circuit of claim 6, wherein the first local oscillator and the second local oscillator have substantially the same characteristic impedance.

8. The circuit of claim 1, further comprising:
a first amplifier connected to the first port of the fourth quadrature hybrid coupler for amplifying the first output signal to a first amplified signal; and
a second amplifier connected to the fourth port of the fourth quadrature hybrid coupler for amplifying the second output signal to a second amplified signal.

9. The circuit of claim 8, further comprising:
a first antenna connected to the first amplifier for transmitting the first amplified signal; and
a second antenna connected to the second amplifier for transmitting the second amplified signal.

10. The circuit of claim 9, wherein the first antenna is for being vertically polarized, and the second antenna is for being horizontally polarized.

11. The circuit of claim 1, wherein the first variable load, the second variable load, the third variable load, and the fourth variable load each comprise a capacitor, a butterfly radio frequency choke, and a Schottky diode.

12. The circuit of claim 1, wherein the circuit comprises complementary metal-oxide-semiconductor (CMOS) components.

13. A circuit comprising:
a first variable load and a second variable load;
a 90-degree phase shifter;
a first power divider and a second power divider, each power divider comprising an input port, a first output port, and a second output port; and
a first quadrature hybrid coupler and a second quadrature hybrid coupler, each quadrature hybrid coupler comprising a first port, a second port, a third port, and a fourth port,
wherein:
the first port of the first quadrature hybrid coupler is for being energized by a first oscillation signal,
the second port of the first quadrature hybrid coupler is connected to the second output port of the first power divider,
the third port of the first quadrature hybrid coupler is connected to the second output port of the second power divider,
the fourth port of the first quadrature hybrid coupler is for being energized by a second oscillation signal,
the first port of the second quadrature hybrid coupler is for being energized by a first output signal,
the second port of the second quadrature hybrid coupler is connected to the first output port of the first power divider via the 90-degree phase shifter,
the third port of the second quadrature hybrid coupler is connected to the first output port of the second power divider,
the fourth port of the second quadrature hybrid coupler is for being energized by a second output signal,
the input port of the first power divider is connected to the first variable load,
the input port of the second power divider is connected to the second variable load,
the first output signal comprises a first modulated signal and a second modulated signal, and
the second output signal comprises a third modulated signal and a fourth modulated signal.

14. The circuit of claim 13, further comprising:
a first local oscillator for generating the first oscillation signal; and
a second local oscillator for generating the second oscillation signal.

15. The circuit of claim 14, wherein the first local oscillator and the second local oscillator have substantially the same characteristic impedance.

16. The circuit of claim 13, further comprising:
a first amplifier connected to the first port of the second quadrature hybrid coupler for amplifying the first output signal to a first amplified signal; and
a second amplifier connected to the fourth port of the second quadrature hybrid coupler for amplifying the second output signal to a second amplified signal.

17. The circuit of claim 16, further comprising:
a first antenna connected to the first amplifier for transmitting the first amplified signal; and
a second antenna connected to the second amplifier for transmitting the second amplified signal.

18. A method comprising:
providing a first oscillating signal and a second oscillating signal to ports of a first quadrature hybrid coupler interconnected to a second quadrature hybrid coupler, the first quadrature hybrid coupler and the second quadrature hybrid coupler interconnected with a first variable network and a second variable network; and
adjusting reflection coefficients of the first variable network and the second variable network to produce a first output signal and a second output signal from ports of the second quadrature hybrid coupler,
wherein the first output signal comprises a first modulated signal and a second modulated signal, and
wherein the second output signal comprises a third modulated signal and a fourth modulated signal.

19. The method of claim 18, wherein the first variable network comprises a first variable load network, and the second variable network comprises a second variable load network.

20. The method of claim 19, wherein the adjusting the reflection coefficients comprises adjusting loads of the first variable load network and the second variable load network.
